(19) United States
(12) Patent Application Publication
(10) Pub. No.: US 2002/0146921 A1
(43) Pub. Date: Oct. 10, 2002

(54) Pin connector

(76) Inventors: Qun Lu, Lexington, MA (US); Dayu Qu, Brighton, MA (US); Alan J. Eaton, N. Smithfield, RI (US); Bryant E. Palmer, West Yarmouth, MA (US)

Correspondence Address: BRIAN J. COLANDREO, Fish & Richardson P.C., 225 Franklin Street, Boston, MA, 02110-2804, US

(21) Appl. No.: 09/828,773

(22) Filed: Apr. 9, 2001

(51) Int. Cl. H05K 1/00

(52) U.S. Cl. 439/83

(57) ABSTRACT

A pin connector system includes a pin portion having a first cross-sectional geometry, wherein the pin portion passes through a pin passage in a first printed circuit board. The pin passage has a second cross-sectional geometry, wherein the combination of the first and second cross-sectional geometries forms a first solder passage for allowing solder to flow through the first printed circuit board.

### TECHNICAL FIELD

This invention relates to pin connectors, and more particularly to pin connectors utilizing soldered connections..

### BACKGROUND

Pin connectors are utilized on printed circuit boards and various electrical devices to connect various electrical and electronic components and connections to them. Typically these pins are soldered in a passage in the device to which they are attached so that an electrical connection can be established.

Pin connectors typical incorporate some type of flange which prevents the pin from passing through or falling into the device to which it is being connected. Unfortunately, the flange creates problems when it is used in connection with printed circuit boards. Specifically, printed circuits boards tend to be multi-layered, meaning that in addition to the conducting foil on the top and bottom surfaces of the printed circuit board, additional isolated layers of conducting foil are embedded within the printed circuit board. This allows the designers of the printed circuit board to incorporate more circuits paths (or traces) into the printed circuit boards.

Unfortunately, when pin connectors incorporating flanges are used in conjunction with multi-layered circuit boards, problems are encountered during solder reflow processes. Specifically, when the pins are installed into the printed circuit boards, the flange will contact one surface of the printed circuit board. This will essentially seal the passage into which the pin is placed, as the combination of the pin and the flange functions like a stopper to effectively seal the passage. Accordingly, as this passage is sealed, solder will not be able to flow through the passage during the reflow process. Therefore, a quality low-resistance electrical connection will not be established between the pin and the various layers of the multi-layer printed circuit board.

### SUMMARY

According to an aspect of this invention, a pin connector system includes a pin portion having a first cross-sectional geometry; wherein the pin portion passes through a pin passage in a first printed circuit board. The pin passage has a second cross-sectional geometry, wherein the combination of the first and second cross-sectional geometries forms a first solder passage for allowing solder to flow through the first printed circuit board.

One or more of the following features may also be included. The pin connector portion includes a first distal end, a second distal end, and a mounting flange positioned radially about the pin portion between the first and second distal ends. The flange is positioned proximate a first surface of the first printed circuit board. The pin connector system further includes a standoff flange, positioned radially about the pin portion and proximate the first distal end of the pin portion, for spacing a second printed circuit board a fixed distance away from the first printed circuit board. The mounting flange includes at least one radial trough, wherein the combination of the at least one radial trough and the first surface of the first printed circuit board establishes a second solder passage which extends the first solder passage across the flange surface. The first and second geometries are configured to form an interference fit between the pin portion and the pin passage. The first printed circuit board is a multi-layer printed circuit board. The second cross-sectional geometry is a circle. The first cross-sectional geometry is a circle. The first cross-sectional geometry is a hexagon. The first cross-sectional geometry is a square. The first cross-sectional geometry is a star.

According to a further aspect of this invention, a pin connector system includes a pin portion having a first distal end and a second distal end. The pin portion has a first cross-sectional geometry, wherein the pin portion includes a mounting flange, positioned radially about the pin portion between the first and second distal ends. The pin portion passes through a pin passage in a first printed circuit board and the pin passage has a second cross-sectional geometry. The flange is positioned proximate a first surface of the first printed circuit board and the combination of the first and second cross-sectional geometries forms a first solder passage for allowing solder to flow from a second surface of the first printed circuit board to the flange.

One or more of the following features may also be included. The pin connector system further includes a standoff flange, positioned radially about the pin portion and proximate the first distal end of the pin portion, for spacing a second printed circuit board a fixed distance away from the first printed circuit board. The mounting flange includes at least one radial trough, wherein the combination of the at least one radial trough and the first surface of the first printed circuit board establishes a second solder passage which extends the first solder passage across the flange surface. The first and second geometries are configured to form an interference fit between the pin portion and the pin passage. The first printed circuit board is a multi-layer printed circuit board. The second cross-sectional geometry is a circle. The first cross-sectional geometry is a circle. The first cross-sectional geometry is a hexagon. The first cross-sectional geometry is a square. The first cross-sectional geometry is a star.

According to a further aspect of this invention, a pin connector system includes a pin having a first distal end and a second distal end. The pin includes a mounting flange, positioned radially about the pin between the first and second distal ends and forming a first and second pin portion, wherein the first pin portion has a first cross-sectional geometry. The first pin portion passes through a pin passage in a first printed circuit board, wherein the pin passage has a second cross-sectional geometry. The flange is positioned proximate a first surface of the first printed circuit board and the combination of the first and second cross-sectional geometries forms a first solder passage for allowing solder to flow from a second surface of the first printed circuit board to the flange.

One or more of the following features may also be included. The pin connector system further includes a standoff flange, positioned radially about the pin and proximate the first distal end of the pin, for spacing a second printed circuit board a fixed distance away from the first printed circuit board. The mounting flange includes at least one radial trough, wherein the combination of the at least one radial trough and the first surface of the first printed circuit board establishes a second solder passage which extends the first solder passage across the flange surface. The first and second geometries are configured to form an interference fit between the first pin portion and the pin passage. The first printed circuit board is a multi-layer printed circuit board. The second cross-sectional geometry is a circle. The first cross-sectional geometry is a circle. The first cross-sectional geometry is a hexagon. The first cross-sectional geometry is a square. The first cross-sectional geometry is a star.

According to a further aspect of this invention, a pin connector system includes a pin portion having a first cross-sectional geometry. A first printed circuit board has a pin passage passing through the first printed circuit board, wherein the pin portion passes through the pin passage. The pin passage has a second cross-sectional geometry and the combination of the first and second cross-sectional geometries forms a first solder passage for allowing solder to flow through the first printed circuit board.

One or more of the following features may also be included. The pin portion includes a first distal end, a second distal end, and a mounting flange positioned radially about the pin portion between the first and second distal ends. The flange is positioned proximate a first surface of the first printed circuit board. The pin connector system further includes a standoff flange, positioned radially about the pin portion and proximate the first distal end of the pin portion, for spacing a second printed circuit board a fixed distance away from the first printed circuit board. The mounting flange includes at least one radial trough, wherein the combination of the at least one radial trough and the first surface of the first printed circuit board establishes a second solder passage which extends the first solder passage across the flange surface. The first and second geometries are configured to form an interference fit between the pin portion and the pin passage.

According to a further aspect of this invention, a method for creating a low resistance electrical connection between a pin connector and a multi-layer printed circuit board includes: manufacturing a pin connector having a first cross-sectional geometry; manufacturing a printed circuit board including a pin passage that passes through the printed circuit board, wherein the pin passage has a second cross-sectional geometry; inserting the pin connector into the printed circuit board, wherein the combination of the first geometry and the second geometry form a solder passage passing through the printed circuit board; and initiating a solder reflow process, wherein solder flows through said solder passage.

One or more advantages can be provided from the above. A pin connector can be used on a multi-layer printed circuit board. A low resistance electrical connection can be established between each foil conductor layer and the pin connector. By establishing a solder passage between the pin connector and the multi-layer printed circuit board, each foil layer can each be soldered to the pin connector.

The details of one or more embodiments of the invention are set forth in the accompanying drawings and the description below. Other features, objects, and advantages of the invention will be apparent from the description and drawings, and from the claims.

### DESCRIPTION OF DRAWINGS

FIG. 1 is a diagrammatic view of the pin connector system;

FIGS. 2A-2H are cross-sectional views of the pin connector system; and

FIG. 3 is a flow chart showing a method for creating a low resistance electrical connection.

Like reference symbols in the various drawings indicate like elements.

### DETAILED DESCRIPTION

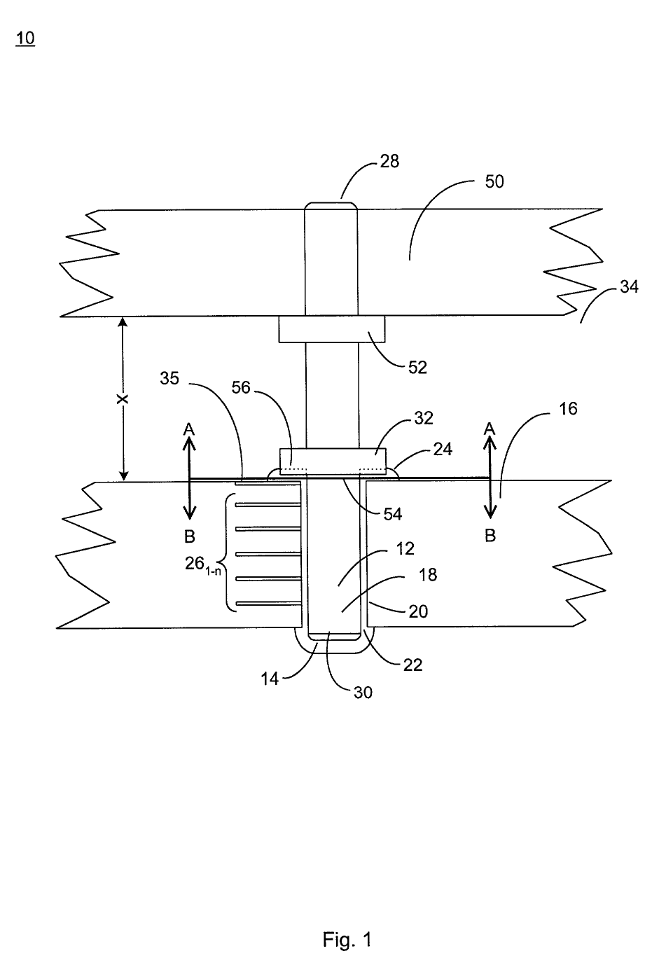

There is shown in FIG. 1, a pin connector system 10, which includes pin 12. Pin 12 passes through pin passage 14 in printed circuit board 16. Pin 12 has a first cross-sectional geometry 18 that is different from the cross-sectional geometry 20 of pin passage 14. Specifically, it is important that the cross-sectional geometry (or shape) 18 of pin portion 12 be different from the cross-sectional geometry (or shape) 20 of pin passage 14. In the event that their cross-sectional geometries (or shapes) are identical, pin 12 would essentially seal pin passage 14 in printed circuit board 16. Irrespective of the geometries of pin 12 and pin passage 14, these devices can be sized to form an interference fit between pin 12 and pin passage 14. Thus, during assembly of printed circuit board 16, pin 12 is pressed into pin passage 14, wherein this interference fit holds pin 12 in place until the connection can be soldered.

The combination of the first cross-sectional geometry 18 and the second cross-sectional geometry 20 forms a solder passage 22 for allowing solder 24 to flow through printed circuit board 16. This is important during a solder reflow process, as the solder passes through pin passage 14 and contacts each conductive foil layer 26₁₋ₙ of printed circuit board 16. Accordingly, a solid low-resistance electrical connection can be established between pin portion 12 and foil layers 26₁₋ₙ.

Pin portion 12 includes a first distal end 28 and a second distal end 30. A mounting flange 32 is positioned between first and second distal ends 28 and 30. Mounting flange 32 is typically a radial flange having a circular cross-sectional shape. However, mounting flange 32 can be configured in whatever shape is most applicable to the user's requirements. During installation of pin 12 into pin passage 14, mounting flange 32 contacts the top surface 34 of printed circuit board 16. Accordingly, mounting flange 32 regulates the depth to which pin 12 is inserted into printed circuit board 16. By allowing solder to flow through printed circuit board 16 via solder passage 22, a low resistance electrical connection can be established between mounting flange 32 and the top conductive foil layer 35 on top surface 34 of printed circuit board 16.

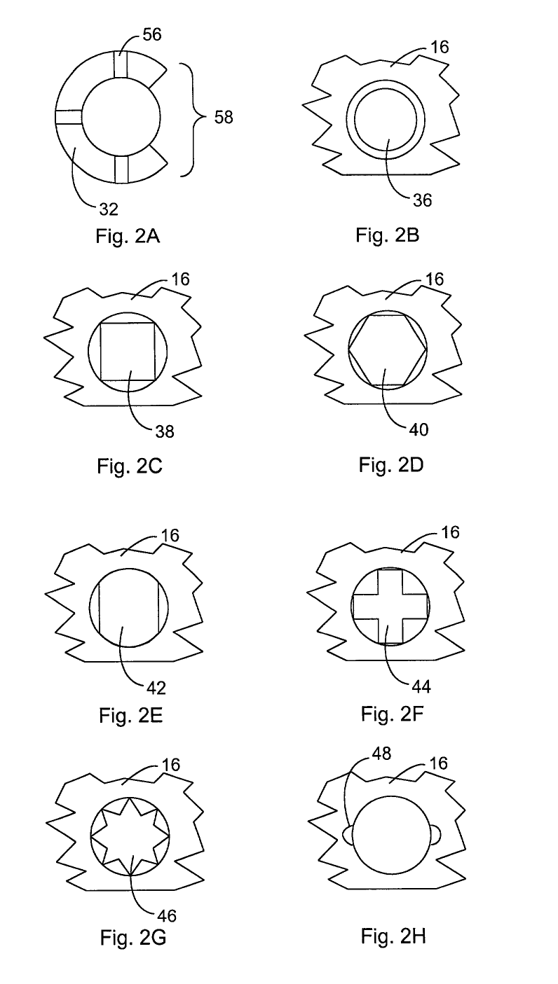

As mounting flange 32 typically contacts top surface 34 of printed circuit board 16, it is possible for mounting flange 32 to seal solder passage(s) 22, thus preventing the flow of solder through solder passages 22. Accordingly, the lower surface 54 of mounting flange 32 includes one or more radial troughs 56 which connect to solder passage(s) 22, thus allowing solder 24 to flow through circuit board 16 and past mounting flange 32. Alternatively, as illustrated in FIG. 2A (a section view taken across section line A-A of FIG. 1), mounting flange 32 can be a semicircular flange wherein a portion 58 of mounting flange 32 is removed to allow solder 24 to flow.

Typically, pin passage 14 will have a circular cross-sectional geometry and pin 12 will have a complimentary geometry that enables the formation of a solder passage 22. However, these geometries can be in any shape desired by the user. The following geometry examples display a cross-sectional view of pin 12 taken across section line B-B. The cross-sectional geometry 18 of pin 12 can be circular (FIG. 2B, 36), square (FIG. 2C, 38), hexagonal (FIG. 2D, 40), circular with recesses (FIG. 2E, 42), cross-shaped (FIG. 2F, 44), or star-shaped (FIG. 2G, 46). Additionally, pin passage 14 need not be circular, as it can include one or more notches (FIG. 2H, 48) so that when this pin passage is utilized in conjunction with a circular pin, one or more solder passages are formed through notches 48. Alternatively, pin passage 14 can have a non-circular geometry, such as square (not shown). It is important to note that the specific shape of pin 12 and passage 14 is not important, as long as the combination of these two shapes forms a passage for solder to flow through.

Pin connector system 10 is typically utilized to connect circuit board 16 to an auxiliary (or daughter) circuit board 50. If pin connector system 10 is used for this application, a standoff flange 52 is incorporated into pin 12. Typically, standoff flange 50 is a radial flange having a circular cross-sectional shape. However, standoff flange 52 can be configured in whatever shape is most applicable to the user's requirements. Standoff flange 52 is typically positioned proximate the first distal end 28 of pin 12 and is utilized to space auxiliary circuit board 50 a fixed distance “x” away from printed circuit board 16.

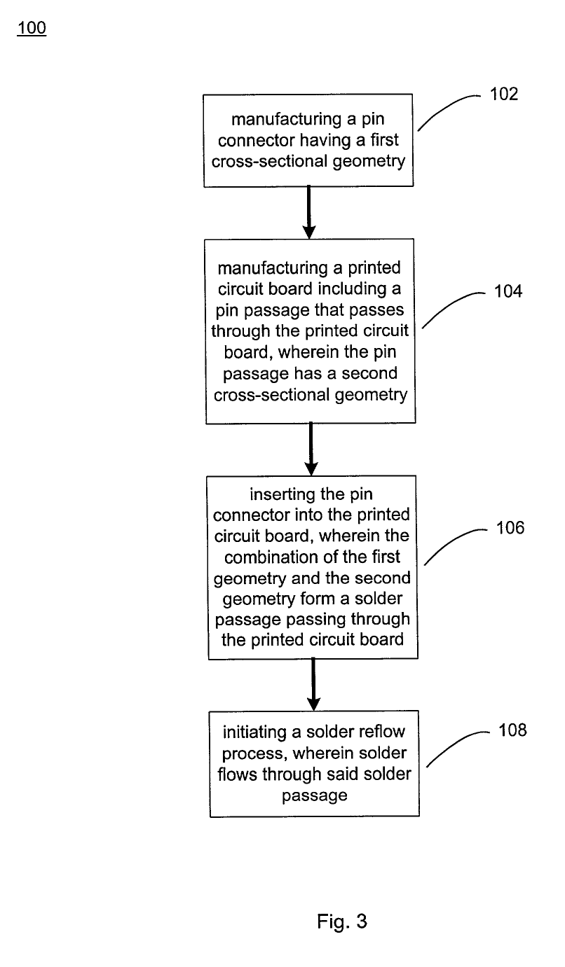

There is shown in FIG. 3, a method 100 for creating a low resistance electrical connection between a pin connector and a multi-layer printed circuit board. In this method, a pin connector having a first cross-sectional geometry is manufactured (102) and a printed circuit board including a pin passage that passes through the printed circuit board is also manufactured (104). This pin passage has a second cross-sectional geometry that is different than the first cross-sectional geometry of the pin connector. The pin connector is inserted into the pin passage of the printed circuit board (106). The combination of the first geometry and the second geometry form a solder passage passing through the printed circuit board. In a solder reflow process, the solder is allowed to flow through the solder passage (108).

A number of embodiments of the invention have been described. Nevertheless, it will be understood that various modifications may be made without departing from the spirit and scope of the invention. Accordingly, other embodiments are within the scope of the following claims.

What is claimed is:

1. A pin connector system comprising:
a pin portion having a first cross-sectional geometry;
wherein said pin portion passes through a pin passage in a first printed circuit board, said pin passage having a second cross-sectional geometry;
wherein the combination of said first and second cross-sectional geometries forms a first solder passage for allowing solder to flow through said first printed circuit board.

2. The pin connector system of claim 1 wherein said pin portion includes a first distal end, a second distal end, and a mounting flange positioned radially about said pin portion between said first and second distal ends, wherein said flange is positioned proximate a first surface of said first printed circuit board.

3. The pin connector system of claim 2 further comprising a standoff flange, positioned radially about said pin portion and proximate said first distal end of said pin portion, for spacing a second printed circuit board a fixed distance away from said first printed circuit board.

4. The pin connector system of claim 2 wherein said mounting flange includes at least one radial trough, wherein the combination of said at least one radial trough and said first surface of said first printed circuit board establishes a second solder passage which extends said first solder passage across said flange surface.

5. The pin connector system of claim 1 wherein said first and second geometries are configured to form an interference fit between said pin portion and said pin passage.

6. The pin connector system of claim 1 wherein said first printed circuit board is a multi-layer printed circuit board.

7. The pin connector system of claim 1 wherein said second cross-sectional geometry is a circle.

8. The pin connector system of claim 1 wherein said first cross-sectional geometry is a circle.

9. The pin connector system of claim 1 wherein said first cross-sectional geometry is a hexagon.

10. The pin connector system of claim 1 wherein said first cross-sectional geometry is a square.

11. The pin connector system of claim 1 wherein said first cross-sectional geometry is a star.

12. A pin connector system comprising:
a pin portion having a first distal end and a second distal end, said pin portion having a first cross-sectional geometry;
wherein said pin portion includes a mounting flange, positioned radially about said pin portion between said first and second distal ends,
wherein said pin portion passes through a pin passage in a first printed circuit board, said pin passage having a second cross-sectional geometry;
wherein said flange is positioned proximate a first surface of said first printed circuit board and the combination of said first and second cross-sectional geometries forms a first solder passage for allowing solder to flow from a second surface of said first printed circuit board to said flange.

13. The pin connector system of claim 12 further comprising a standoff flange, positioned radially about said pin portion and proximate said first distal end of said pin portion, for spacing a second printed circuit board a fixed distance away from said first printed circuit board.

14. The pin connector system of claim 12 wherein said mounting flange includes at least one radial trough, wherein the combination of said at least one radial trough and said first surface of said first printed circuit board establishes a second solder passage which extends said first solder passage across said flange surface.

15. The pin connector system of claim 12 wherein said first and second geometries are configured to form an interference fit between said pin portion and said pin passage.

16. The pin connector system of claim 12 wherein said first printed circuit board is a multi-layer printed circuit board.

17. The pin connector system of claim 12 wherein said second cross-sectional geometry is a circle.

18. The pin connector system of claim 12 wherein said first cross-sectional geometry is a circle.

19. The pin connector system of claim 12 wherein said first cross-sectional geometry is a hexagon.

20. The pin connector system of claim 12 wherein said first cross-sectional geometry is a square.

21. The pin connector system of claim 12 wherein said first cross-sectional geometry is a star.

22. A pin connector system comprising:
a pin having a first distal end and a second distal end;
wherein said pin includes a mounting flange, positioned radially about said pin between said first and second distal ends and forming a first and second pin portion, wherein said first pin portion has a first cross-sectional geometry;
wherein said first pin portion passes through a pin passage in a first printed circuit board, said pin passage having a second cross-sectional geometry;
wherein said flange is positioned proximate a first surface of said first printed circuit board and the combination of said first and second cross-sectional geometries forms a first solder passage for allowing solder to flow from a second surface of said first printed circuit board to said flange.

23. The pin connector system of claim 22 further comprising a standoff flange, positioned radially about said pin and proximate said first distal end of said pin, for spacing a second printed circuit board a fixed distance away from said first printed circuit board.

24. The pin connector system of claim 22 wherein said mounting flange includes at least one radial trough, wherein the combination of said at least one radial trough and said first surface of said first printed circuit board establishes a second solder passage which extends said first solder passage across said flange surface.

25. The pin connector system of claim 22 wherein said first and second geometries are configured to form an interference fit between said first pin portion and said pin passage.

26. The pin connector system of claim 22 wherein said first printed circuit board is a multi-layer printed circuit board.

27. The pin connector system of claim 22 wherein said second cross-sectional geometry is a circle.

28. The pin connector system of claim 22 wherein said first cross-sectional geometry is a circle.

29. The pin connector system of claim 22 wherein said first cross-sectional geometry is a hexagon.

30. The pin connector system of claim 22 wherein said first cross-sectional geometry is a square.

31. The pin connector system of claim 22 wherein said first cross-sectional geometry is a star.

32. A pin connector system comprising:
a pin portion having a first cross-sectional geometry;
a first printed circuit board having a pin passage passing through said first printed circuit board;
wherein said pin portion passes through said pin passage, said pin passage having a second cross-sectional geometry;
wherein the combination of said first and second cross-sectional geometries forms a first solder passage for allowing solder to flow through said first printed circuit board.

33. The pin connector system of claim 32 wherein said pin portion includes a first distal end, a second distal end, and a mounting flange positioned radially about said pin portion between said first and second distal ends, wherein said flange is positioned proximate a first surface of said first printed circuit board.

34. The pin connector system of claim 32 further comprising a standoff flange, positioned radially about said pin portion and proximate said first distal end of said pin portion, for spacing a second printed circuit board a fixed distance away from said first printed circuit board.

35. The pin connector system of claim 32 wherein said mounting flange includes at least one radial trough, wherein the combination of said at least one radial trough and said first surface of said first printed circuit board establishes a second solder passage which extends said first solder passage across said flange surface.

36. The pin connector system of claim 32 wherein said first and second geometries are configured to form an interference fit between said pin portion and said pin passage.

37. A method for creating a low resistance electrical connection between a pin connector and a multi-layer printed circuit board, comprising:
manufacturing a pin connector having a first cross-sectional geometry;
manufacturing a printed circuit board including a pin passage that passes through the printed circuit board, wherein the pin passage has a second cross-sectional geometry;
inserting the pin connector into the pin passage of the printed circuit board, wherein the combination of the first geometry and the second geometry form a solder passage passing through the printed circuit board; and
initiating a solder reflow process, wherein solder flows through said solder passage.
